(19) United States
(12) Patent Application Publication
(10) Pub. No.: US 2026/0173634 A1
(43) Pub. Date: Jun. 18, 2026

(54) DISPLAY DEVICE AND MANUFACTURING METHOD OF DISPLAY DEVICE

(71) Applicant: LG Display Co., Ltd., Seoul (KR)

(72) Inventors: Dohyeon KIM, Paju-si (KR); Sangwoo HAN, Paju-si (KR); Heewon LEE, Paju-si (KR); Sanghak SHIN, Paju-si (KR)

(73) Assignee: LG Display Co., Ltd., Seoul (KR)

(21) Appl. No.: 19/238,206

(22) Filed: Jun. 13, 2025

(30) Foreign Application Priority Data
Dec. 13, 2024 (KR) 10-2024-0186264

(51) Int. Cl. H10H 29/80; H10H 29/01; H10H 29/37; H10H 29/49; H10H 29/855

(52) U.S. Cl. CPC H10H 29/882; H10H 29/012; H10H 29/0363; H10H 29/37; H10H 29/49; H10H 29/855

(57) ABSTRACT

This application relates to a display device and method for manufacturing display device. The display device may include a substrate, a first pad on the substrate, and a bonding layer on the first pad. A second pad is on the bonding layer and electrically connected to the first pad. A first light emitting element is on the second pad and include a first electrode electrically connected to the second pad. A first partition wall is between the substrate and the first light emitting element, connecting to one side of the first pad, one side of the bonding layer, and one side of the second pad. A second partition wall may be similarly disposed to connect to another side of the first pad, another side of the bonding layer, and another side of the second pad. These structures may help reduce short circuits and improve bonding reliability in the display device.

### CROSS-REFERENCE TO RELATED APPLICATION

This application claims priority from Korean Patent Application No. 10-2024-0186264, filed on Dec. 13, 2024, which is hereby incorporated by reference for all purposes as if fully set forth herein.

### BACKGROUND

### Technical Field

Embodiments of the disclosure relate to a display device and a method for manufacturing the display device.

### Description of the Related Art

Typically, in conventional display panel manufacturing methods, a panel substrate is formed, and then, light emitting elements are bonded to the substrate. This process is a sequential process which may have difficulty in decreasing the processing time.

Recently, developments are being made to enable mass production or large-scale panel manufacturing of display panels for display devices, shorten panel manufacturing times, and enable eco-friendly panel manufacturing.

The description provided in the discussion of the related art section should not be assumed to be prior art merely because it is mentioned in or associated with that section. The discussion of the related art section may include information that describes one or more aspects of the subject technology, and the description in this section does not limit the present disclosure.

### BRIEF SUMMARY

The disclosed display device and manufacturing method introduce a partition wall structure disposed between the substrate and the light-emitting element, physically connecting to the first pad, bonding layer, and second pad to prevent short circuits during bonding. By fabricating the upper (light-emitting element) and lower (substrate and pad) layers separately and concurrently, then bonding them using an anisotropic conductive film (ACF), the process reduces manufacturing time and enables mass production. The bonding layer provides vertical electrical connectivity while limiting lateral conduction, and the partition walls add mechanical isolation and alignment.

Additionally, an optical layer containing fine particles surrounds the light-emitting elements to enhance light extraction efficiency through scattering. Partition walls can be implemented in the lower layer, upper layer, or both, allowing design flexibility. Post-bonding integration of layers such as a common electrode and transparent insulating film, with conductive adhesive layers providing electrical connections, completes the display structure while ensuring electrical performance and optical clarity.

For example, various embodiments of the disclosure may provide a display device and a method for manufacturing the display device, which may decrease the panel manufacturing time and enable mass production.

Embodiments of the disclosure may provide a display device and a method for manufacturing the display device, which enables eco-friendly panel manufacturing.

Embodiments of the disclosure may provide a display device and a method for manufacturing the display device, which may reduce the panel defect rate.

Embodiments of the disclosure may provide a display device and a method for manufacturing the display device, which may reduce or prevent a short circuit between pads.

Benefits of embodiments of the disclosure are not limited to those set forth herein, and other unmentioned benefits would be apparent to one of ordinary skill in the art from the following description.

Embodiments of the disclosure may provide a display device comprising a substrate, a first pad disposed on the substrate, a bonding layer disposed on the first pad, a second pad disposed on the bonding layer and electrically connected to the first pad, a first light emitting element disposed on the second pad and having a first electrode (e.g., an anode electrode) electrically connected to the second pad, and a first partition wall disposed between the substrate and the first light emitting element and disposed to connect to one side of the first pad, one side of the bonding layer, and one side of the second pad, and a second partition wall disposed between the substrate and the first light emitting element and disposed to connect to another side of the first pad, another side of the bonding layer, and another side of the second pad.

Embodiments of the disclosure may provide a method for manufacturing a display device, comprising composing a lower layer portion by sequentially forming a first sacrificial layer, a substrate, and a first pad on a first glass, composing an upper layer portion by sequentially forming a second sacrificial layer, a first light emitting element, and a second pad on a second glass, bonding the upper layer portion onto the lower layer portion, and removing the first glass, the first sacrificial layer, the second sacrificial layer, and the second glass, wherein after the bonding, the first pad and the second pad is electrically connected to each other by a bonding layer disposed between the first pad and the second pad and, after the bonding, a first partition wall disposed between the substrate and the first light emitting element and disposed to connect to one side of the first pad, one side of the bonding layer, and one side of the second pad and a second partition wall disposed between the substrate and the first light emitting element and disposed to connect to another side of the first pad, another side of the bonding layer, and another side of the second pad are formed.

According to embodiments of the disclosure, there may be provided a display device capable of decreasing the panel manufacturing time and enable mass production.

According to embodiments of the disclosure, there may be provided a display device capable of reducing greenhouse gas by optimizing the panel manufacturing process.

Embodiments of the disclosure may provide a display device and a method for manufacturing the display device, which may reduce the defect rate of the display panel by including a barrier wall in the display panel.

The effects of the disclosure are not limited to the foregoing benefits, and other effects will be apparent to one of ordinary skill in the art from the following detailed description.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The disclosure will be more fully understood from the following detailed description and the accompanying drawings, which are provided for illustration only and are not intended to limit the disclosure.

FIG. 1 is a view illustrating a configuration of a display device according to embodiments of the disclosure;

FIG. 2 is a view illustrating a circuit structure of a subpixel according to embodiments of the disclosure;

FIG. 3 is a cross-sectional view illustrating a display panel according to embodiments of the disclosure;

FIG. 4 is a diagram illustrating an order of manufacturing a display panel according to embodiments of the disclosure;

FIGS. 5 to 7 illustrate a manufacturing process for forming a partition wall on a lower layer portion of a panel according to embodiments of the disclosure;

FIG. 8 illustrates a process of bonding an upper layer portion and a lower layer portion in FIG. 7 according to embodiments of the disclosure;

FIGS. 9 to 11 illustrate a manufacturing process for forming a partition wall on an upper layer portion of a panel according to embodiments of the disclosure;

FIG. 12 illustrates a process of bonding a lower layer portion and an upper layer portion in FIG. 11 according to embodiments of the disclosure; and

FIG. 13 illustrates a process of bonding an upper layer portion having a partition wall and a lower layer portion having a partition wall according to embodiments of the disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments may be provided so that this disclosure may be sufficiently thorough and complete to assist those skilled in the art to fully understand the scope of the present disclosure. Further, the present disclosure is only defined by scopes of claims.

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted or may be briefly provided when it is determined that the description may make the subject matter in some embodiments of the disclosure rather unclear. The terms such as “including,” “having,” “containing,” “constituting” “make up of”, and “formed of” used herein are generally intended to allow other components to be added unless the terms are used with the term “only.” As used herein, singular forms are intended to include plural forms unless the context clearly indicates otherwise.

Any implementation described herein as an “example” is not necessarily to be construed as preferred or advantageous over other implementations.

Terms, such as “first,” “second,” “A,” “B,” “(A),” or “(B)” may be used herein to describe elements of the disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it may be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

To elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when any dimensions, relative sizes, etc., are mentioned, it may be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure. Furthermore, the present disclosure is only defined by scopes of claims.

It will be apparent to those skilled in the art that various modifications and variations can be made in the display device and a method for manufacturing the display device of the present disclosure without departing from the technical idea or scope of the disclosures. Thus, it is intended that the present disclosure covers the modifications and variations of this disclosure provided they come within the scope of the appended claims and their equivalents.

Hereinafter, various embodiments of the disclosure are described in detail with reference to the accompanying drawings.

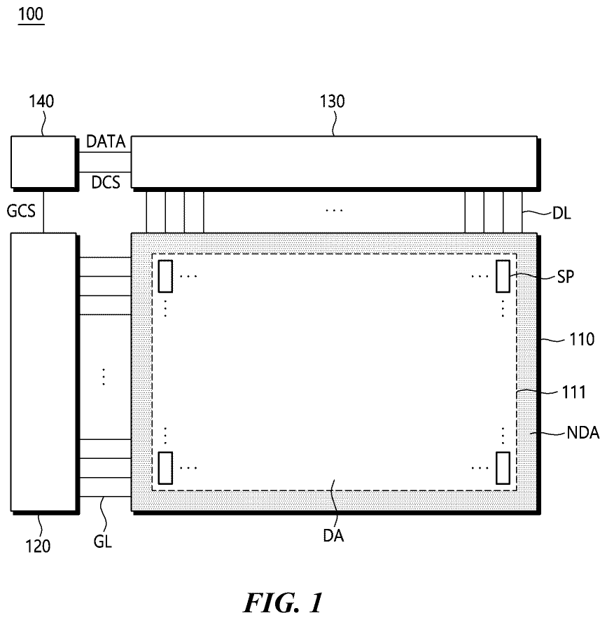

FIG. 1 is a view illustrating a configuration of a display device 100 according to embodiments of the disclosure.

Referring to FIG. 1, the display device 100 may include a display panel 110, a data driving circuit 130, a gate driving circuit 120, and a controller 140.

The display panel 110 may include a display area DA in which images are displayed and a non-display area NDA in which no image is displayed.

The display panel 110 may include a substrate 111, a plurality of subpixels SP disposed on the substrate 111, and various types of signal lines for driving the plurality of subpixels SP. The plurality of subpixels SP may be disposed in the display area DA.

Various types of signal lines may include a plurality of data lines DL transferring data signals (also referred to as data voltages or image signals) and a plurality of gate lines GL transferring gate signals (also referred to as scan signals). The plurality of data lines DL and the plurality of gate lines GL may cross each other.

Each of the plurality of data lines DL may be disposed while extending in a first direction. Each of the plurality of gate lines GL may be disposed while extending in a second direction. Here, the first direction may be a column direction and the second direction may be a row direction. The first direction may be the row direction, and the second direction may be the column direction. For convenience of description, it is assumed below that data line DL is disposed in the column direction and gate line GL is disposed in the row direction.

The data driving circuit 130 is a circuit for driving the data lines DL, and may output data signals to the data lines DL. The gate driving circuit 120 is a circuit for driving the gate lines GL, and may output gate signals to the gate lines GL. The controller 140 is a device for controlling the data driving circuit 130 and the gate driving circuit 120 and may control driving timings for the data lines DL and driving timings for the gate lines GL.

The controller 140 may supply a data driving control signal DCS to the data driving circuit 130 to control the data driving circuit 130 and may supply a gate driving control signal GSC to the gate driving circuit 120 to control the gate driving circuit 120.

The data driving circuit 130 may supply data signals DATA to the plurality of data lines DL according to the driving timing control by the controller 140. The data driving circuit 130 may receive digital image data from the controller 140 and may convert the received image data into analog data signals and output them to the plurality of data lines DL.

The gate driving circuit 120 may supply gate signals to the plurality of gate lines GL according to the timing control of the controller 140. The gate driving circuit 120 may receive a first gate voltage corresponding to a turn-on level voltage and a second gate voltage corresponding to a turn-off level voltage, along with various gate driving control signals (e.g., start signal and reset signal), generate gate signals, and supply the generated gate signals to the plurality of gate lines GL.

For example, the data driving circuit 130 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110. For convenience of description, it is assumed below that the data driving circuit 130 is connected to the display panel 110 as a chip-on-film COF type.

The gate driving circuit 120 may be connected with the display panel 110 by TAB method or connected to a bonding pad of the display panel 110 by a COG or COP method or may be connected with the display panel 110 according to a COF method. Alternatively, the gate driving circuit 120 may be formed as a gate in panel (GIP) type, in the non-active area or the active area of the display panel 110.

Meanwhile, at least one of the data driving circuit 130 and the gate driving circuit 120 may be disposed in the active area of the display panel 110. For example, at least one of the data driving circuit 130 and the gate driving circuit 120 may be disposed not to overlap the subpixels SP, or the whole or part of at least one of the data driving circuit 130 and the gate driving circuit 120 may be disposed to overlap the subpixels SP.

The data driving circuit 130 may be connected to one side (e.g., an upper or lower side) of the display panel 110. Depending on the driving scheme or the panel design scheme, data driving circuits 130 may be connected with both the sides (e.g., both the upper and lower sides) of the display panel 110, or two or more of the four sides of the display panel 110.

The gate driving circuit 120 may be connected to one side (e.g., a left or right side) of the display panel 110. Depending on the driving scheme or the panel design scheme, gate driving circuits 120 may be connected with both the sides (e.g., both the left and right sides) of the display panel 110, or two or more of the four sides of the display panel 110.

The controller 140 may be implemented as a separate component from the data driving circuit 130, or the controller 140 and the data driving circuit 130 may be integrated into an integrated circuit (IC). The controller 140 may be a timing controller used in typical display technology, a control device that may perform other control functions as well as the functions of the timing controller, or a control device other than the timing controller, or may be a circuit in the control device. The controller 140 may be implemented as various circuits or electronic components, such as an integrated circuit (IC), a field programmable gate array (FPGA), an application specific integrated circuit (ASIC), or a processor.

The controller 140 may be mounted on a printed circuit board or a flexible printed circuit and may be electrically connected with the data driving circuit 130 and the gate driving circuit 120 through the printed circuit board or the flexible printed circuit. The controller 140 may transmit/receive signals to/from the data driving circuit 130 according to one or more predetermined interfaces. The interface may include, e.g., a low voltage differential signaling (LVDS) interface, an EPI interface, and a serial peripheral interface (SPI).

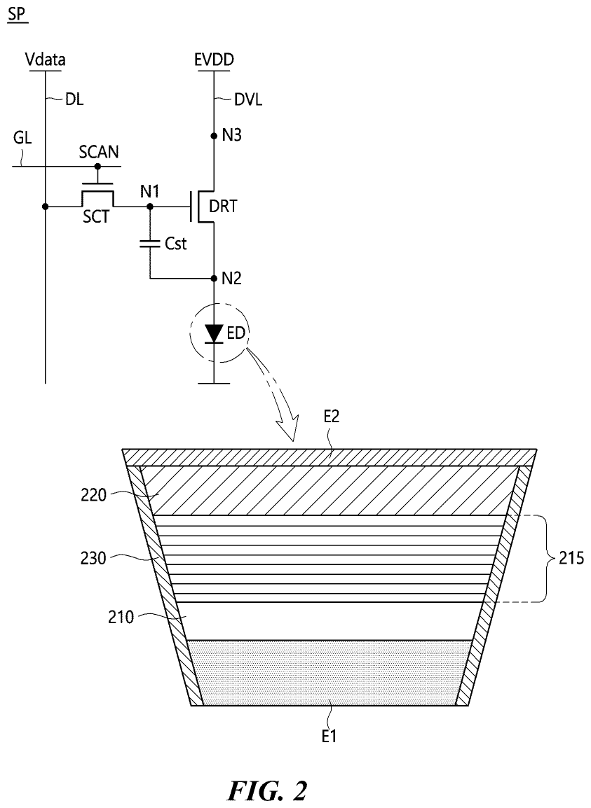

FIG. 2 is a view illustrating a circuit structure of a subpixel SP disposed on a display device 100 according to embodiments of the disclosure.

Referring to FIG. 2, the subpixel SP disposed on the display panel 110 of the display device 100 according to embodiments of the disclosure may include one or more transistors and a capacitor and may have a light emitting element ED disposed therein. For example, the subpixel SP may include a driving transistor DRT, a scan transistor SCT, a storage capacitor Cst, and a light emitting element ED.

The driving transistor DRT is a transistor for driving the light emitting element ED, and may include a first node N1, a second node N2, and a third node N3.

The first node N1 of the driving transistor DRT may be a gate node of the driving transistor DRT, and may be electrically connected with a source node or a drain node of the scan transistor SCT. The second node N2 of the driving transistor DRT may be a source node or a drain node of the driving transistor DRT, and may be electrically connected to the pixel electrode PE of the light emitting element ED. The third node N3 of the driving transistor DRT may be electrically connected with a driving voltage line DVL supplying a driving voltage EVDD.

The scan transistor SCT may be controlled by a scan pulse SCAN, which is a type of gate signal, and may be connected between the first node N1 of the driving transistor DRT and the data line DL. In other words, the scan transistor SCT may be turned on or off according to the scan pulse SCAN supplied from the scan line SCL, which is a type of the gate line GL, controlling the connection between the data line DL and the first node N1 of the driving transistor DRT.

The scan transistor SCT may be turned on by the scan pulse SCAN having a turn-on level voltage and transfer the data signal Vdata supplied from the data line DL to the first node N1 of the driving transistor DRT.

If the scan transistor SCT is an n-type transistor, the turn-on level voltage of the scan pulse SCAN may be a high level voltage. If the scan transistor SCT is a p-type transistor, the turn-on level voltage of the scan pulse SCAN may be a low level voltage.

The storage capacitor Cst may be electrically connected between the first node N1 and second node N2 of the driving transistor DRT. The storage capacitor Cst is charged with the quantity of electric charge corresponding to the voltage difference between both ends thereof and serves to maintain the voltage difference between both ends for a predetermined frame time. Accordingly, during the predetermined frame time, the corresponding subpixel SP may emit light.

FIG. 2 illustrates a light emitting element ED in a display panel 110 according to embodiments of the disclosure.

Each of the plurality of light emitting elements ED disposed in the display panel 110 according to embodiments of the disclosure may be an inorganic material-based light emitting diode LED. For example, each of the plurality of light emitting elements ED may be a micro light emitting diode (micro LED). For example, each of the plurality of light emitting elements ED may be a vertical light emitting diode.

Each of the plurality of light emitting elements ED may include a first electrode E1, a first semiconductor layer 210, an active layer 215, a second semiconductor layer 220, and a second electrode E2.

For example, the first electrode E1 may be an anode electrode, and the second electrode E2 may be a cathode electrode. As another example, the first electrode E1 may be a cathode electrode, and the second electrode E2 may be an anode electrode.

For example, the first electrode E1 may include at least one of gold (Au), copper (Cu), tin (Sn), titanium (Ti), aluminum (Al), and silver (Ag). For example, the second electrode E2 may be formed of a transparent metal material (transparent conductive material: TCO) such as indium tin oxide (ITO) and indium zinc oxide (IZO) that may transmit light.

The first semiconductor layer 210 may be disposed on the first electrode E1. For example, the first semiconductor layer 210 may be a p-type semiconductor and may include a semiconductor material having a formula of AlxGayIn1-x-yN(0≤x≤1, 0≤y≤1, 0≤x+y≤1), but the disclosure is not limited thereto. For example, the semiconductor material included in the first semiconductor layer 210 may be any one or more of AlGaInN, GaN, AlGaN, InGaN, AlN, and InN doped to be p-type, but the disclosure is not limited thereto. The first semiconductor layer 210 may be doped with a p-type dopant, and the p-type dopant may be Mg, Zn, Ca, Se, Ba, or the like, but the disclosure is not limited thereto. For example, the first semiconductor layer 210 may be p-GaN doped with p-type Mg, but the disclosure is not limited thereto.

Meanwhile, the light emitting element ED may further include an electron blocking layer disposed on the first semiconductor layer 210. The electron blocking layer may be a layer for suppressing or preventing too many electrons from flowing to the active layer 215. For example, the electron blocking layer may be p-AlGaN doped with p-type Mg, but the disclosure is not limited thereto. The electron blocking layer may be omitted.

The active layer 215 may be disposed on the first semiconductor layer 210 or the electron blocking layer. The active layer 215 may emit light by a combination of an electron-hole pair according to an electric signal applied through the first semiconductor layer 210 and the second semiconductor layer 220. The active layer 215 may emit one of first color light, second color light, and third color light. For example, the first color light may be red light, the second color light may be green light, and the third color light may be blue light.

The active layer 215 may include a material having a single or multi-quantum well structure. When the active layer 215 includes a material having a multi-quantum well structure, it may have a structure in which a plurality of well layers and barrier layers may be alternately stacked. In this case, the well layer may be formed of InGaN, and the barrier layer may be formed of GaN or AlGaN, but the disclosure is not limited thereto.

Alternatively, the active layer 215 may have a structure in which semiconductor materials with high bandgap energy and semiconductor materials with low bandgap energy are alternately stacked, or may include group 3 to group 5 semiconductor materials that differ according to the wavelength band of light emitted. For example, when indium is included among the semiconductor materials included in the active layer 215, the color of the emitted light may vary according to the content of indium. For example, as the content of indium increases, light of a long wavelength band may be emitted. For example, if the indium content is about 15%, it may emit light in a blue wavelength band, if the indium content is about 25%, it may emit light in a green wavelength band, and if the indium content is about 35% or more, it may emit light in a red wavelength band.

Meanwhile, the light emitting element ED may further include a superlattice layer disposed on the active layer 215. The superlattice layer may be a layer for relieving stress between the second semiconductor layer 220 and the active layer 215. For example, the superlattice layer may be formed of InGaN or GaN. The superlattice layer may be omitted.

The second semiconductor layer 220 may be disposed on the active layer 215 or the superlattice layer. For example, the second semiconductor layer 220 may be an n-type semiconductor and may include a semiconductor material having a formula of AlxGayIn1-x-yN(0≤x≤1, 0≤y≤1, 0≤x+y≤1), but the disclosure is not limited thereto. For example, the semiconductor material included in the second semiconductor layer 220 may be one or more of AlGaInN, GaN, AlGaN, InGaN, AlN, and InN doped to be n-type, but the disclosure is not limited thereto. For example, the second semiconductor layer 220 may be doped with an n-type dopant, and the n-type dopant may be Si, Ge, Sn, or the like, but the disclosure is not limited thereto. For example, the second semiconductor layer 220 may be n-GaN doped with n-type Si, but the disclosure is not limited thereto.

The second electrode E2 may be disposed on the second semiconductor layer 220.

The light emitting element ED may further include an insulation film 230 for protecting the light emitting element ED.

The insulation film 230 may be disposed on a side surface of the first electrode E1.

The insulation film 230 may be disposed on the side surfaces of the first semiconductor layer 210, the second semiconductor layer 220, and the active layer 215.

For example, the insulation film 230 may be formed of any one selected from a silicon oxide film (SiOx) and a silicon nitride film (SiNx), or a stacked structure thereof.

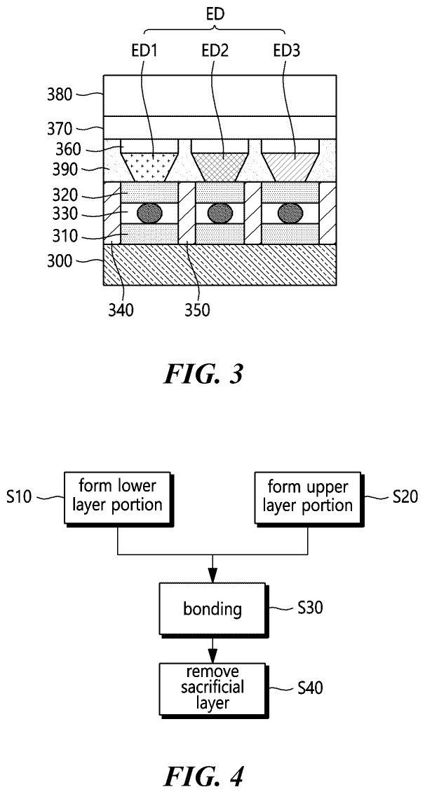

FIG. 3 is a cross-sectional view of a display panel 110 according to embodiments of the disclosure.

The first pad 310 may be disposed on the substrate 300.

The first pad may be a metallic material.

The bonding layer 330 may be disposed on the first pad 310.

The second pad 320 is disposed on the bonding layer 330 and may be electrically connected to the first pad 310.

The first light emitting element ED1 is disposed on the second pad 320 and may have a first electrode E1 electrically connected to the second pad 320. For example, the first electrode E1 may be an anode electrode.

The first partition wall 340 may be disposed between the substrate 300 and the first light emitting element ED1, and may be disposed to connect to one side of the first pad 310, one side of the bonding layer 330, and one side of the second pad 320.

The second partition wall 350 may be disposed between the substrate 300 and the first light emitting element ED1, and may be disposed to connect to the other side of the first pad 310, the other side of the bonding layer 330, and the other side of the second pad 320.

The above description may be equally applied to the second light emitting element ED2 and the third light emitting element ED3.

The bonding layer 330 may include an anisotropic conductive film (ACF).

An optical layer 390 surrounding the first light emitting element ED1 may be further included. The optical layer 390 may include fine particles.

The optical layer 390 may include an organic insulating material where fine particles are dispersed, but embodiments of the disclosure are not limited thereto. For example, the optical layer 390 may be formed of siloxane where fine metal particles such as titanium dioxide (TiO2) particles are dispersed, but embodiments of the disclosure are not limited thereto. Light from the plurality of light emitting elements ED may be scattered by the fine particles dispersed in the optical layer 390 and emitted to the outside of the display device 100. Accordingly, the optical layer 390 may enhance extraction efficiency of light emitted from the plurality of light emitting elements ED.

The transparent insulation layer 380 may be disposed on the light emitting element ED. The transparent insulation layer 380 may be formed of an organic material.

The adhesive layer 360 may be disposed between the light emitting element ED and the transparent insulation layer 380.

The common electrode 370 may be disposed on the light emitting element ED and may be electrically connected to the first electrode E1 of the light emitting element ED.

The adhesive layer 360 may be disposed between the light emitting element ED and the common electrode 370, and the common electrode 370 may be electrically connected to the first electrode E1 of the light emitting element through a hole of the adhesive layer 360. The adhesive layer 360 may include a conductive material.

The common electrode 370 may be electrically connected to the first electrode E1 of the light emitting element ED through the adhesive layer 360.

FIG. 4 is a diagram illustrating an order of manufacturing a display panel 110 according to embodiments of the disclosure.

It may include a lower layer portion forming step S10 of composing a lower layer portion, an upper layer portion forming step S20 of composing an upper layer portion, a step S30 of bonding the upper layer portion to the lower layer portion, and a step S40 of removing a sacrificial layer and a glass.

The processes of the lower layer portion forming step S10 and the upper layer portion forming step S20 may be performed concurrently (or in some embodiments, simultaneously).

In order to manufacture the display panel 110 where the partition wall as shown in FIG. 3 is formed, three embodiments of the disclosure may be described. The method of forming the partition wall is not limited thereto.

The partition wall may be formed only in the lower layer portion or only in the upper layer portion, or may be formed in both the lower layer portion and the upper layer portion.

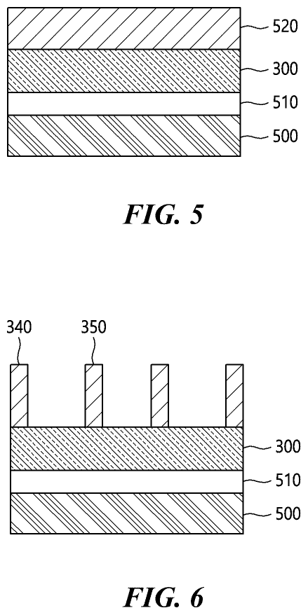

FIGS. 5 to 7 illustrate a manufacturing process for forming a partition wall on a lower layer portion of a panel according to embodiments of the disclosure.

In FIG. 5, in the lower layer portion, a sacrificial layer 510, a substrate 300, and an insulation layer 520 may be sequentially formed on a first glass 500.

In FIG. 6, the insulation layer 520 of the lower layer portion may be etched to form partition walls including the first partition wall 340 and the second partition wall 350.

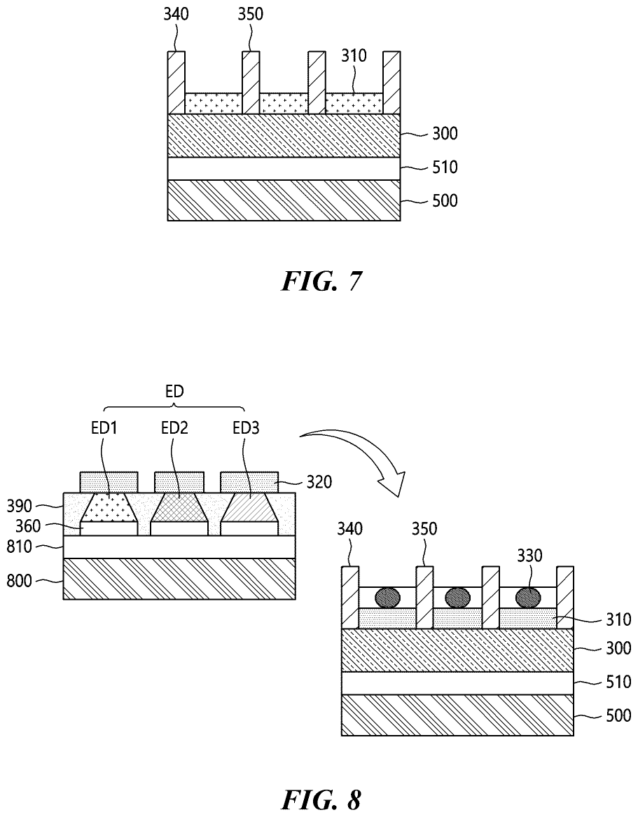

In FIG. 7, a first pad 310 may be formed between the first partition wall 340 and the second partition wall 350.

FIG. 8 is a view illustrating a process of bonding an upper layer portion and a lower layer portion where a partition wall of FIG. 7 is formed according to embodiments of the disclosure.

The step of composing the lower layer portion may include a step of forming the first partition wall 340 and the second partition wall 350 on the substrate 300.

In the upper layer portion, a sacrificial layer 810, an adhesive layer 360, a light emitting element ED, and a second pad 320 may be sequentially formed on the second glass 800. An optical layer 390 may be further formed between the light emitting elements ED.

The upper layer portion may be bonded to the lower layer portion where the partition walls including the first partition wall and the second partition wall are formed as shown in FIG. 7.

The first pad of the lower layer portion and the second pad of the upper layer portion may be electrically connected by a bonding layer. The bonding layer may include an anisotropic conductive film (ACF).

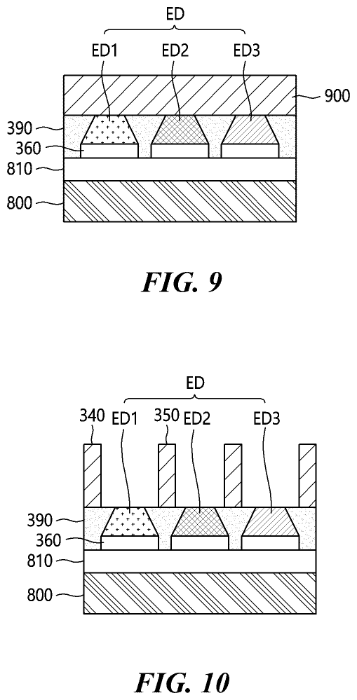

FIGS. 9 to 11 are views illustrating a process of manufacturing a partition wall on an upper layer portion of a panel according to embodiments of the disclosure.

In FIG. 9, in an upper layer portion, a sacrificial layer, an adhesive layer, a light emitting element, and an insulation layer may be formed on a second glass.

The step of composing the upper layer portion may include a step of forming the optical layer 390 surrounding the first light emitting element ED1 and a step of forming the first partition wall 340 and the second partition wall 350 on the optical layer 390.

An optical layer 390 surrounding the light emitting element ED including the first light emitting element ED1 and the second light emitting element ED2 and the third light emitting element ED3 may be formed.

In FIG. 10, partition walls including the first partition wall 340 and the second partition wall 350 may be formed by etching the insulation layer 900 of the upper layer portion. The etching area may be an area corresponding to the first electrode on the light emitting element. The first partition wall 340 and the second partition wall 350 may include an organic material.

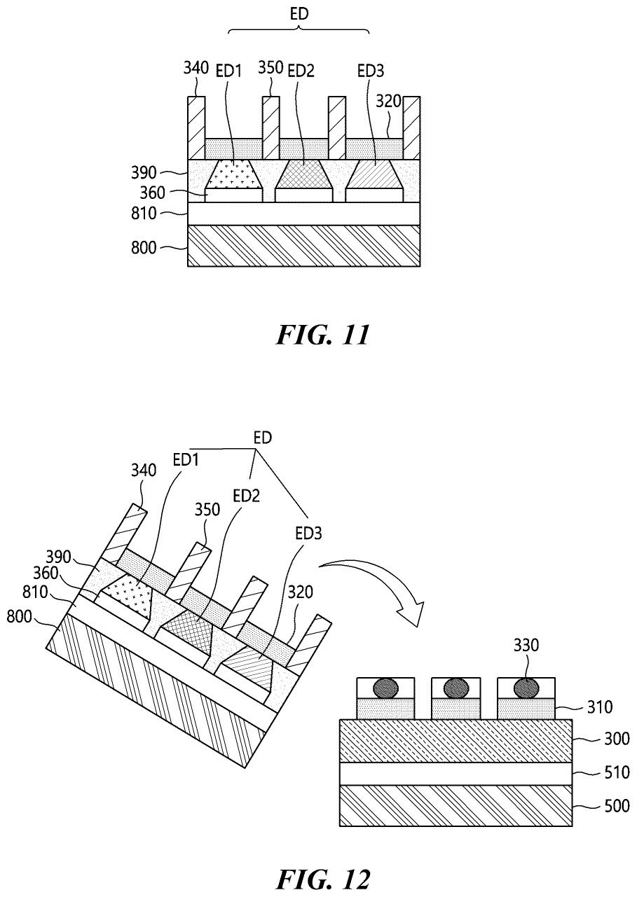

In FIG. 11, the second pad 320 may be formed between the first partition wall 340 and the second partition wall 350.

FIG. 12 is a view illustrating a process of bonding an upper layer portion where a partition wall of FIG. 11 is formed onto a lower layer portion according to embodiments of the disclosure.

In the lower layer portion, a sacrificial layer 510, a substrate 300, and a first pad 310 may be sequentially formed on the first glass 500.

The upper layer portion where the partition wall of FIG. 11 is formed may be bonded onto the lower layer portion. The first pad 310 of the lower layer portion and the second pad 320 of the upper layer portion may be electrically connected to each other by a bonding layer 330. The bonding layer 330 may include an anisotropic conductive film (ACF).

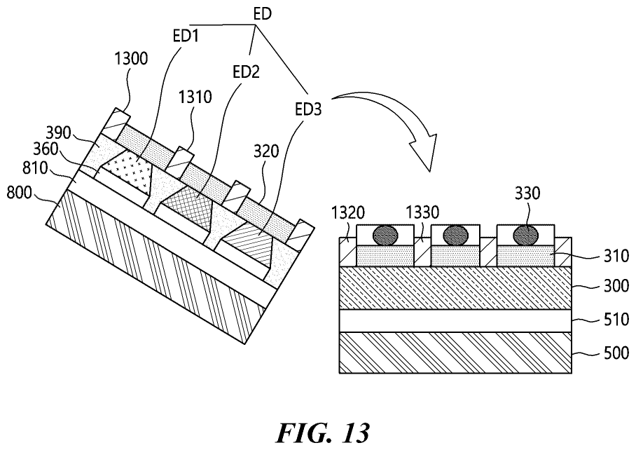

FIG. 13 is a view illustrating a process of bonding an upper layer portion having a partition wall and a lower layer portion having a partition wall according to embodiments of the disclosure.

A sacrificial layer 510, a substrate 300, a first pad 310, a first lower partition wall 1320, and a second lower partition wall 1330 may be sequentially formed on the first glass 500.

In the upper layer portion, a sacrificial layer 810, an adhesive layer 360, a light emitting element ED, a second pad 320, a first upper partition wall 1300, and a second upper partition wall 1310 may be formed on the second glass 800. An optical layer may be further formed between the first light emitting element ED1 and the second light emitting element ED2. An optical layer 390 may be formed between the light emitting elements ED.

The lengths of the first lower partition wall 1320, the second lower partition wall 1330, the first upper partition wall 1300, and the second upper partition wall 1310 may be half the lengths of the first partition wall 340 and the second partition wall 350. The first lower partition wall 1320, the second lower partition wall 1330, the first upper partition wall 1300, and the second upper partition wall 1310 may include an organic material.

An upper layer portion where the first upper partition wall 1300 and the second upper partition wall 1310 are formed may be bonded onto a lower layer portion where the first lower partition wall 1320 and the second lower partition wall 1330 are formed.

The lower layer portion and the upper layer portion may be electrically connected to each other by a bonding layer 330. The first pad 310 and the second pad 320 may be electrically connected to each other by the bonding layer 330. The bonding layer 330 may include an anisotropic conductive film (ACF).

According to the above-described embodiments of the disclosure, it is possible to decrease the processing time by separately manufacturing the lower layer portion and the upper layer portion. Process productivity may be enhanced by decreasing the processing time.

Further, it is possible to reduce or prevent a short circuit that may occur between the pads by forming a partition wall between the first pad 310 and the second pad 320.

A display device according to an embodiment of the disclosure may be described as follows.

A display device according to an embodiment of the disclosure may include a first pad disposed on a substrate, a bonding layer disposed on the first pad, a second pad disposed on the bonding layer and electrically connected to the first pad, a first light emitting element disposed on the second pad and having a first electrode electrically connected to the second pad, and a first partition wall disposed between the substrate and the first light emitting element and disposed to connect to one side of the first pad, one side of the bonding layer, and one side of the second pad, and a second partition wall disposed between the substrate and the first light emitting element and disposed to connect to another side of the first pad, another side of the bonding layer, and another side of the second pad.

For example, the first electrode may be an anode electrode.

The first partition wall and the second partition wall may include an organic material.

The bonding layer may include an anisotropic conductive film (ACF).

The display device may further include an optical layer surrounding the first light emitting element.

The optical layer may include fine particles.

The display device may further include a transparent insulation layer disposed on the first light emitting element.

The display device may further include an adhesive layer disposed between the light emitting element and the transparent insulation layer.

The display device may further include a common electrode disposed on the light emitting element and electrically connected to a second electrode of the light emitting element.

The display device may further include an adhesive layer disposed between the light emitting element and the common electrode.

The common electrode may be electrically connected to the second electrode of the light emitting element through a hole of the adhesive layer.

The display device may further include an adhesive layer disposed between the light emitting element and the common electrode and including a conductive material.

The common electrode may be electrically connected to the second electrode of the light emitting element through the adhesive layer.

A method for manufacturing a display device, according to an embodiment of the disclosure, may include composing a lower layer portion by sequentially forming a first sacrificial layer, a substrate, and a first pad on a first glass, composing an upper layer portion by sequentially forming a second sacrificial layer, a first light emitting element, and a second pad on a second glass, bonding the upper layer portion onto the lower layer portion, and removing the first glass, the first sacrificial layer, the second sacrificial layer, and the second glass. After the bonding, the first pad and the second pad may be electrically connected to each other by a bonding layer disposed between the first pad and the second pad and, after the bonding, a first partition wall disposed between the substrate and the first light emitting element and disposed to connect to one side of the first pad, one side of the bonding layer, and one side of the second pad and a second partition wall disposed between the substrate and the first light emitting element and disposed to connect to another side of the first pad, another side of the bonding layer, and another side of the second pad may be formed.

Composing the lower layer portion may include forming the first partition wall and the second partition wall on the substrate.

Composing the upper layer portion may include forming an optical layer surrounding the first light emitting element, and forming the first partition wall and the second partition wall on the optical layer.

Composing the lower layer portion may include forming a first lower partition wall and a second lower partition wall on the substrate. Composing the upper layer portion may include forming an optical layer surrounding the first light emitting element, and forming a first upper partition wall and a second upper partition wall on the optical layer. After the bonding, the first lower partition wall and the first upper partition wall may contact each other to compose the first partition wall, and the second lower partition wall and the second upper partition wall may contact each other to compose the second partition wall.

The method may further include, after the removing, forming a common electrode on the first light emitting element, and forming a transparent insulation layer on the common electrode.

In the bonding, the first pad and the second pad may be bonded to each other by an anisotropic conductive film (ACF).

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the technical idea and scope of the disclosure. The above description and the accompanying drawings provide an example of the technical idea of the disclosure for illustrative purposes only. That is, the disclosed embodiments are intended to illustrate the scope of the technical idea of the disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate;
a first pad on the substrate;
a bonding layer on the first pad;
a second pad on the bonding layer and electrically connected to the first pad;
a first light emitting element on the second pad and having a first electrode electrically connected to the second pad; and
a first partition wall extending from the substrate and contacting one side of the first pad, one side of the bonding layer, and one side of the second pad; and
a second partition wall extending from the substrate and contacting another side of the first pad, another side of the bonding layer, and another side of the second pad.

2. The display device of claim 1, wherein the first partition wall and the second partition wall include an organic material.

3. The display device of claim 1, wherein the bonding layer includes an anisotropic conductive film.

4. The display device of claim 1, further comprising an optical layer surrounding the first light emitting element.

5. The display device of claim 4, wherein the optical layer includes fine particles.

6. The display device of claim 1, further comprising a transparent insulation layer on the first light emitting element.

7. The display device of claim 6, further comprising an adhesive layer between the light emitting element and the transparent insulation layer.

8. The display device of claim 1, further comprising a common electrode on the light emitting element and electrically connected to a second electrode of the light emitting element.

9. The display device of claim 8, further comprising an adhesive layer between the light emitting element and the common electrode,
wherein the common electrode is electrically connected to the second electrode of the light emitting element through a hole of the adhesive layer.

10. The display device of claim 8, further comprising an adhesive layer between the light emitting element and the common electrode and including a conductive material,
wherein the common electrode is electrically connected to the second electrode of the light emitting element through the adhesive layer.

11. A method for manufacturing a display device, the method comprising:
composing a lower layer portion by sequentially forming a first sacrificial layer, a substrate, and a first pad on a first glass;
composing an upper layer portion by sequentially forming a second sacrificial layer, a first light emitting element, and a second pad on a second glass;
bonding the upper layer portion onto the lower layer portion; and
removing the first glass, the first sacrificial layer, the second sacrificial layer, and the second glass,
wherein after the bonding the upper layer portion onto the lower layer portion, the first pad and the second pad are electrically connected to each other by a bonding layer disposed between the first pad and the second pad, and
wherein after the bonding the upper layer portion onto the lower layer portion, a first partition wall disposed between the substrate and the first light emitting element and disposed to connect to one side of the first pad, one side of the bonding layer, and one side of the second pad and a second partition wall disposed between the substrate and the first light emitting element and disposed to connect to another side of the first pad, another side of the bonding layer, and another side of the second pad are formed.

12. The method of claim 11, wherein composing the lower layer portion includes forming the first partition wall and the second partition wall on the substrate.

13. The method of claim 11, wherein composing the upper layer portion includes:
forming an optical layer surrounding the first light emitting element; and
forming the first partition wall and the second partition wall on the optical layer.

14. The method of claim 11, wherein composing the lower layer portion includes:
forming a first lower partition wall and a second lower partition wall on the substrate, wherein composing the upper layer portion includes:
forming an optical layer surrounding the first light emitting element; and
forming a first upper partition wall and a second upper partition wall on the optical layer, and
wherein after the bonding the upper layer portion onto the lower layer portion, the first lower partition wall and the first upper partition wall contact each other to compose the first partition wall, and the second lower partition wall and the second upper partition wall contact each other to compose the second partition wall.

15. The method of claim 11, further comprising:
after the removing the first glass, forming a common electrode on the first light emitting element; and
forming a transparent insulation layer on the common electrode.

16. The method of claim 11, wherein in the bonding the upper layer portion onto the lower layer portion, the first pad and the second pad are bonded to each other by an anisotropic conductive film.

17. A display panel comprising:
a lower layer portion including:
a substrate; and
a first pad on the substrate;
an upper layer portion including:
a light emitting element; and
a second pad disposed below the light emitting element;
a bonding layer between the first pad and the second pad to electrically connect the first pad and the second pad;
a first partition wall extending from the substrate toward the light emitting element and disposed to contact a first side of the first pad, the bonding layer, and the second pad;
a second partition wall extending from the substrate toward the light emitting element and disposed to contact a second side of the first pad, the bonding layer, and the second pad.

18. The display panel of claim 17, further comprising:
an optical layer surrounding the light emitting element and including fine particles,
wherein the fine particles of the optical layer, in operation, enhances light extraction.

19. The display panel of claim 17, wherein the first side is opposite of the second side.

20. The display panel of claim 17, wherein the lower layer portion and the upper layer portion are separately fabricated and bonded together through the bonding layer.
